(19) United States
(12) Patent Application Publication
(10) Pub. No.: US 2024/0154587 A1
(43) Pub. Date: May 9, 2024

(54) CLASS-D AUDIO AMPLIFICATION CIRCUITRY AND ELECTRONIC DEVICE INCLUDING THE SAME

(71) Applicant: Samsung Electronics Co., Ltd., Suwon-si (KR)

(72) Inventor: Ji-Hun LEE, Suwon-si (KR)

(73) Assignee: Samsung Electronics Co., Ltd., Suwon-si (KR)

(21) Appl. No.: 18/456,914

(22) Filed: Aug. 28, 2023

(30) Foreign Application Priority Data
Nov. 4, 2022 (KR) 10-2022-0146254

(51) Int. Cl. H03F 3/217; H03F 1/26

(52) U.S. Cl. CPC H03F 3/2171; H03F 1/26; H03F 2200/03; H03F 2200/351

(57) ABSTRACT

Class-D amplification circuitry includes an operational amplifier configured to receive a differential input signal via summing nodes, and output a first signal, a loop filter configured to low-pass filter the first signal, a pulse width modulator configured to perform pulse width modulation on the filtered signal, a gate driver stage configured to generate a gate signal based on the modulated signal, an output stage configured to generate a differential output signal based on the gate signal, and a common mode canceller connected between an input node of the output stage and the summing nodes, the common mode canceller configured to generate an inverted pseudo output signal based on the differential output signal, and provide the inverted pseudo output signal the summing nodes, the inverted pseudo output signal cancelling a common mode noise when applied to a feedback signal provided to the summing nodes.

### CROSS-REFERENCE TO RELATED APPLICATION

This application claims priority from Korean Patent Application No. 10-2022-0146254 filed on Nov. 4, 2022 in the Korean Intellectual Property Office, and all the benefits accruing therefrom under 35 U.S.C. 119, the contents of which in its entirety are herein incorporated by reference.

### BACKGROUND

### Field

The present disclosure relates to audio amplification circuitry, and more specifically, to class D audio amplification circuitry and an electronic device including the same.

### Description of Related Art

A class-D amplifier receives an analog input signal and generates a digital output signal with a low frequency component proportional to the input signal. The advantage of the class-D amplifier over a linear amplifier such as a class-AB amplifier is higher efficiency (up to 100%). One of general applications of the class-D amplifier is a loudspeaker driving circuit. Due to its high efficiency, the class-D audio amplifier may be suitable for being integrated into a SOC (system on chip). An example of the SOC is a baseband processor for a mobile phone, a wireless phone, or a hearing aid.

### SUMMARY

The present disclosure provides for class-D audio amplification circuitry with improved power efficiency so as not to harm (e.g., distort) an audio signal output.

Advantages of the present disclosure are not limited to the above. Other advantages according to the present disclosure that are not mentioned may be understood based on following descriptions, and may be more clearly understood based on embodiments according to the present disclosure. Further, it will be easily understood that the advantages according to the present disclosure may be realized using means shown in the claims and combinations thereof.

Embodiments of the present disclosure provide Class-D amplification circuitry including an operational amplifier configured to receive a differential input signal via summing nodes, and output a first signal, a loop filter configured to low-pass filter the first signal to generate a filtered signal, a pulse width modulator configured to perform pulse width modulation on the filtered signal to generate a modulated signal, a gate driver stage configured to generate a gate signal based on the modulated signal, an output stage configured to generate a differential output signal based on the gate signal, and a common mode canceller connected between an input node of the output stage and the summing nodes, the common mode canceller being configured to generate an inverted pseudo output signal based on the differential output signal, and provide the inverted pseudo output signal the summing nodes, the inverted pseudo output signal cancelling a common mode noise when applied to a feedback signal provided to the summing nodes.

Embodiments of the present disclosure provide Class-D amplification circuitry including an operational amplifier configured to receive a differential input signal and a feedback signal via summing nodes, and output a first signal, a loop filter configured to low-pass filter the first signal to generate a filtered signal, a pulse width modulator configured to perform pulse width modulation on the filtered signal to generate a modulated signal, a gate driver stage configured to generate a gate signal based on the modulated signal, an output stage configured to generate a differential output signal based on the gate signal, and a common mode canceller configured to generate an inverted pseudo signal based on the modulated signal, and provide the inverted pseudo signal to the summing nodes.

Embodiments of the present disclosure provide audio amplification circuitry including an audio output interface for receiving audio data and converting the audio data into a differential input signal, class-D amplification circuitry configured to convert the differential input signal into a pulse-type differential output signal, and amplify the pulse-type differential output signal based on an output power to generate an amplified differential output signal, and a speaker for outputting the amplified differential output signal. The class-D amplification circuit includes an operational amplifier configured to receive the differential input signal and a feedback signal via summing nodes, and output a first signal, a loop filter configured to low-pass filter the first signal to generate a filtered signal, a pulse width modulator configured to perform pulse width modulation on the filtered signal to generate a modulated signal, a gate driver stage configured to generate a gate signal based on the modulated signal, an output stage configured to generate a differential output signal based on the gate signal, a feedback loop path via which the feedback signal is provided to the summing nodes, the feedback signal being based on the differential output signal, and a common mode canceller configured to generate a differential pseudo output signal corresponding to the feedback signal, invert the differential pseudo output signal to generate an inverted differential pseudo output signal, and provide the inverted differential pseudo output signal to the summing nodes.

### BRIEF DESCRIPTION OF DRAWINGS

The above and other aspects and features of the present disclosure will become more apparent by describing in detail embodiments thereof with reference to the attached drawings, in which:

FIG. 1 is a block diagram of an electronic device 101 in a network environment 100 according to embodiments.

FIG. 2 is a block diagram of the audio module 170 according to embodiments.

FIG. 3 is a block diagram showing the audio amplification circuitry according to embodiments.

FIG. 4 is a conceptual diagram showing class-D amplification circuitry 1 according to embodiments.

FIG. 5 is a circuit diagram specifically showing the class-D amplification circuitry of FIG. 4 according to embodiments.

FIG. 6 is a conceptual diagram showing class-D amplification circuitry 2 according to embodiments.

FIG. 7 is a detailed circuit diagram showing the class-D amplification circuitry 2 of FIG. 6 according to embodiments.

### DETAILED DESCRIPTIONS

It will be understood that, although the terms “first”, “second”, “third”, and so on may be used herein to illustrate various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

The features of embodiments of the present disclosure may be partially or entirely combined with each other, and may be technically associated with each other or operate with each other. Embodiments may be implemented independently of each other and/or may be implemented together in an association relationship.

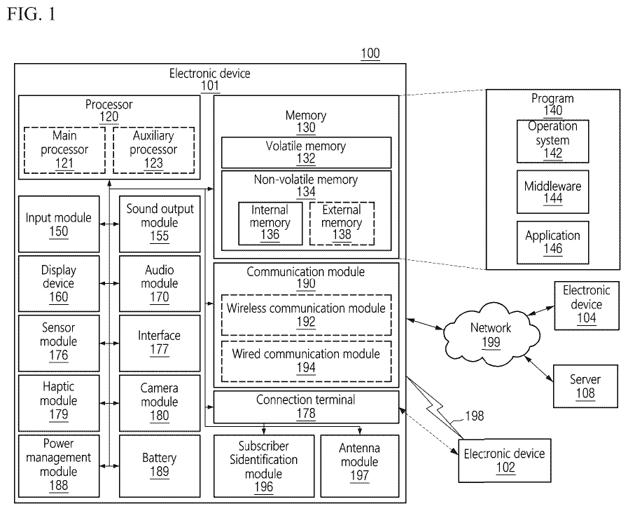

FIG. 1 is a block diagram of an electronic device 101 in a network environment 100 according to embodiments.

Referring to FIG. 1, in the network environment 100, the electronic device 101 may communicate with an electronic device 102 (e.g., a speaker and/or a headphone) through a first network 198 (e.g., a short-range wireless communication network), or may communicate with at least one of an electronic device 104 or a server 108 through a second network 199 (e.g., a long-distance wireless communication network). According to embodiments, the electronic device 101 may communicate with the electronic device 104 through the server 108. According to embodiments, the electronic device 101 may include a processor 120, a memory 130, an input module 150 (also referred to herein as the input device 150), a sound output module 155 (also referred to herein as the sound output device 155), a display device 160, an audio module 170, a sensor module 176, an interface 177, a connection terminal 178, a haptic module 179, a camera module 180, a power management module 188, a battery 189, a communication module 190, a subscriber identification module 196, and/or an antenna module 197. In embodiments, in the electronic device 101, at least one (e.g., the connection terminal 178) of the above components may be omitted or one or more further components may be added. In embodiments, some components (e.g., the sensor module 176, the camera module 180, or the antenna module 197) of the above listed components may be integrated into one component (e.g., the display device 160).

The processor 120 may execute for example, software (e.g., a program 140) to control at least one further component (e.g., a hardware or software component) of the electronic device 101 connected to the processor 120, and to perform various data processing or computing. According to embodiments, in at least a portion of the data processing or computing, the processor 120 may transfer a command or data received from another component (e.g., the sensor module 176 or the communication module 190) to a volatile memory 132, and/or may process such a command or data stored in the volatile memory 132 and store resulting data in a non-volatile memory 134. According to embodiments, the processor 120 may include a main processor 121 (e.g., a central processing unit or an application processor) and/or an auxiliary processor 123 (e.g., a graphic processing unit, a NPU (neural processing unit), an image signal processor, a sensor hub processor, and/or a communication processor) which operates independently of the main processor or in combination the therewith. For example, when the electronic device 101 includes the main processor 121 and the auxiliary processor 123, the auxiliary processor 123 may consume a power amount smaller than that which the main processor 121 consumes, or may be configured to be specialized for a designated function. The auxiliary processor 123 may be implemented separately from the main processor 121 or as a portion thereof.

The auxiliary processor 123 may control at least some of functions or states related to at least one (e.g., the display device 160, the sensor module 176, or the communication module 190) of the components the electronic device 101, for example, on behalf of the main processor 121 while the main processor 121 is in an inactive (e.g., sleep) state, or together with the main processor 121 while the main processor 121 is active (e.g., executes an application). According to embodiments, the auxiliary processor 123 (e.g., an image signal processor or a communication processor) may be implemented as a portion of another component (e.g., the camera module 180 or the communication module 190) functionally related thereto. According to embodiments, the auxiliary processor 123 (e.g., a neural network processing device) may include a hardware structure specialized for processing of an artificial intelligence model (AI model). The AI model may be created via machine learning. The learning may be performed, for example, in the electronic device 101 itself where the artificial intelligence model is performed, or may be performed via a separate server (e.g., the server 108). A learning algorithm may include, for example, supervised learning, semi-supervised learning, or reinforcement learning. However, the present disclosure is not limited thereto. The artificial intelligence model may include a plurality of artificial neural network layers. An artificial neural network may be embodied as one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more thereof. The present disclosure is not limited to the above example. The artificial intelligence model may additionally or alternatively include a software structure in addition to the hardware structure.

The memory 130 may store therein various data used by at least one component (e.g., the processor 120 or the sensor module 176) of the electronic device 101. The data may include, for example, software (e.g., program 140), and input data or output data on a command related thereto. The memory 130 may include the volatile memory 132 or the non-volatile memory 134. According to embodiments, the non-volatile memory may include an internal memory 136 and/or an external memory 138.

The program 140 may be stored as software in the memory 130, and may include, for example, an operating system 142, a middleware 144, and/or an application 146.

The input device 150 may receive a command or data to be used in a component (e.g., the processor 120) of the electronic device 101 from a device or an object (e.g., a user) external to the electronic device 101. The input device 150 may include, for example, a microphone, a mouse, a keyboard, a key (e.g., a button), and/or a digital pen (e.g., a stylus pen).

The sound output device 155 may output a sound signal to an outside out of the electronic device 101. The sound output device 155 may include, for example, a speaker and/or a receiver. The speaker may be used for a general purpose, for example, multimedia playback or recording playback. The receiver may be used to receive an incoming call. According to embodiments, the receiver may be implemented separately from the speaker or as a portion thereof.

The display device 160 may visually provide information to an object (e.g., a user) out of the electronic device 101. The display device 160 may include, for example, a display, a hologram device, and/or a projector, and a control circuit for controlling a corresponding device. According to embodiments, the display device 160 may include a touch sensor configured to detect a touch or a pressure sensor configured to measure an intensity of a force generated by a touch.

The audio module 170 may convert a sound signal into an electrical signal or vice versa. According to embodiments, the audio module 170 may acquire a sound via the input module 150, or may output a sound via the sound output module 155, or via an external electronic device (e.g., the electronic device 102) connected directly or wirelessly to the electronic device 101.

The sensor module 176 may detect an operating state (e.g., a power or a temperature) of the electronic device 101 or an external environment state (e.g., a user state), and may generate an electrical signal or data value corresponding to the detected state. According to embodiments, the sensor module 176 may include, for example, a gesture sensor, a gyro sensor, an air pressure sensor, a magnetic sensor, an acceleration sensor, a grip sensor, a proximity sensor, a color sensor, an IR (infrared) sensor, a biosensor, a temperature sensor, a humidity sensor, and/or an illuminance sensor.

The interface 177 may support one or more specified protocols that may be used to wirelessly or wiredly connect the electronic device 101 to an external electronic device (e.g., the electronic device 102). According to embodiments, the interface 177 may include, for example, a high definition multimedia interface (HDMI), a universal serial bus (USB) interface, an SD card interface, and/or an audio interface.

The connection terminal 178 may include a connector through which the electronic device 101 may be physically connected to an external electronic device (e.g., the electronic device 102). According to embodiments, the connection terminal 178 may include, for example, an HDMI connector, a USB connector, an SD card connector, and/or an audio connector (e.g., a headphone connector).

The haptic module 179 may convert an electrical signal into a mechanical stimulus (e.g., vibration or motion) or an electrical stimulus that the user may perceive using a tactile or kinesthetic sense. According to embodiments, the haptic module 179 may include, for example, a motor, a piezoelectric element, and/or an electrical stimulation device.

The camera module 180 may image a still image and/or a moving image. According to embodiments, the camera module 180 may include one or more lenses, image sensors, image signal processors, and/or flashes.

The power management module 188 may manage power supplied to the electronic device 101. According to embodiments, the power management module 188 may be implemented as at least a portion of a power management integrated circuit (PMIC).

The battery 189 may supply power to at least one component of the electronic device 101. According to embodiments, the battery 189 may include, for example, a non-rechargeable primary battery, a rechargeable secondary battery, and/or a fuel cell.

The communication module 190 may support establishment of a direct (e.g., wired) communication channel or a wireless communication channel between the electronic device 101 and an external electronic device (e.g., the electronic device 102, the electronic device 104, and/or the server 108), and communication through the established communication channel. The communication module 190 may include one or more communication processors that operate independently of the processor 120 (e.g., an application processor) and support direct (e.g., wired) communication or wireless communication therewith. According to embodiments, the communication module 190 may include a wireless communication module 192 (e.g., a cellular communication module, a short-range wireless communication module, or a global navigation satellite system (GNSS) communication module) and/or a wired communication module 194 (e.g., a local area network (LAN) communication module, or a power line communication module). A corresponding communication module among these communication modules may communicate with the external electronic device 104 through the first network 198 (e.g., a short-distance communication network such as Bluetooth, WiFi (wireless fidelity) direct or IrDA (infrared data association)) or the second network 199 (e.g., a long-distance communication network such as a legacy cellular network, a 5G (fifth generation) network, a next-generation communication network, the Internet, or a computer network (e.g., a LAN or wide area network (WAN)). These various types of communication modules may be integrated into one component (e.g., a single chip) or implemented as a plurality of separate components (e.g., multiple chips). The wireless communication module 192 may identify or authenticate the electronic device 101 in a communication network such as the first network 198 or the second network 199 using subscriber information (e.g., International Mobile Subscriber Identifier (IMSI)) stored in the subscriber identification module 196.

The wireless communication module 192 may support a 5G network after a 4G (fourth generation) network and a next-generation communication technology, for example, NR access technology (new radio access technology). The NR access technology may support high-speed transmission of high-capacity data (enhanced mobile broadband (eMBB)), minimization (or reduction) of terminal power, access to multiple terminals (massive machine type communications (mMTC)), and/or higher reliability and lower latency (ultra-reliable and low latency communication (URLLC)). The wireless communication module 192 may support, for example, a high frequency band (e.g., mmWave band) in order to achieve a higher data rate. The wireless communication module 192 may support various technologies for securing performance in a high frequency band, such as beamforming, massive multiple-input and multiple-output (MIMO), full dimensional MIMO (FD-MIMO), an array antenna, analog beam-forming, and/or large scale antenna. The wireless communication module 192 may support various requirements (or qualifications) specified in the electronic device 101, an external electronic device (e.g., the electronic device 104), or a network system (e.g., the second network 199). According to embodiments, the wireless communication module 192 may support a peak data rate (e.g., 20 Gbps or higher) for realizing eMBB, loss coverage (e.g., 164 dB or lower) for realizing mMTC, or U-plane latency (e.g., 0.5 ms or lower, or round trip 1 ms or lower for each of downlink (DL) and uplink (UL)) for realizing URLLC.

The antenna module 197 may transmit or receive a signal or power to or from an external device (e.g., the external electronic device). According to embodiments, the antenna module 197 may include an antenna including a radiator composed of a conductor and/or a conductive pattern formed on a substrate (e.g., a PCB). According to embodiments, the antenna module 197 may include a plurality of antennas (e.g., an array antenna). In this case, for example, at least one antenna suitable for a communication scheme used in a communication network such as the first network 198 or the second network 199 may be selected from the plurality of antennas by the communication module 190. The signal or the power may communicate between the communication module 190 and an external electronic device through the selected at least one antenna. According to embodiments, a further component (e.g., a radio frequency integrated circuit (RFIC)) in addition to the radiator may be additionally formed as a portion of the antenna module 197.

According to embodiments, the antenna module 197 may constitute a mmWave antenna module. According to embodiments, the mmWave antenna module may include a printed circuit board, an RFIC disposed on or adjacent to a first face (e.g., a bottom face) of the printed circuit board and capable of supporting a designated high frequency band (e.g., a mmWave band), and a plurality of antennas (e.g., an array antennas) disposed on or adjacent to a second face (e.g., a top face or side face) of the printed circuit board and capable of transmitting or receiving a signal of the designated high frequency band.

At least some of the components may be connected to each other via a communication scheme (e.g., a bus, a general-purpose input and output (GPIO), a serial peripheral interface (SPI), or a mobile industry processor interface (MIPI)) between peripheral devices, and may exchange a signal (e.g., a command or data) with each other.

According to embodiments, the command or data may be transmitted or received between the electronic device 101 and the external electronic device 104 through the server 108 connected to the second network 199. Each of the external electronic devices 102 and 104 may be of the same type as (or a similar type to) that of the electronic device 101, or of a different type therefrom. According to embodiments, all or some of operations executed in the electronic device 101 may be executed in one or more external electronic devices among the external electronic devices 102, 104, or 108. For example, when the electronic device 101 performs a certain function or service automatically, or in response to a request from a user or another device, the electronic device 101 may request one or more external electronic devices to perform at least a portion of the function or service instead of executing the function or service by itself, or together with executing the function or service itself. Upon receiving the request, the one or more external electronic devices may execute at least a portion of the requested function or service, or an additional function or service related to the request, and deliver the execution result to the electronic device 101. The electronic device 101 may process the result directly or additionally and may provide the processing result as at least a portion of a response to the request. To this end, for example, cloud computing, distributed computing, mobile edge computing (MEC), or client-server computing may be used. The electronic device 101 may provide an ultra-low latency service using, for example, the distributed computing or the mobile edge computing (MEC). In embodiments, the external electronic device 104 may include an Internet of Things (IoT) device. The server 108 may be an intelligent server using machine learning and/or a neural network. According to embodiments, the external electronic device 104 or the server 108 may be included in the second network 199. The electronic device 101 may be applied to an intelligent service (e.g., smart home, smart city, smart car, and/or health care) based on 5G communication technology and IoT related technology.

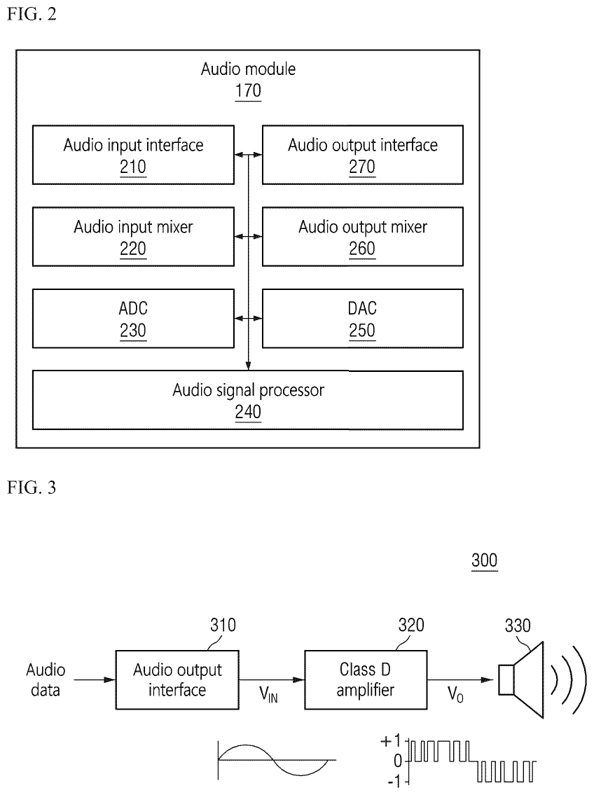

FIG. 2 is a block diagram of the audio module 170 according to embodiments.

Referring to FIG. 2, the audio module 170 may include, for example, an audio input interface 210, an audio input mixer 220, an analog to digital converter (ADC) 230, an audio signal processor 240, a DAC (digital to analog converter) 250, an audio output mixer 260, and/or an audio output interface 270.

The audio input interface 210 may receive an audio signal corresponding to a sound obtained from an outside out of the electronic device 101 through a microphone (e.g., a dynamic microphone, a condenser microphone, and/or a piezo microphone) configured as a portion of the input module 150, or separately from the electronic device. For example, when the audio signal is obtained from the external electronic device 102 (e.g., a headset or a microphone), the audio input interface 210 may be connected directly to the external electronic device 102 via the connection terminal 178 or wirelessly (e.g., Bluetooth communication) through the wireless communication module 192 and may receive the audio signal. According to embodiments, the audio input interface 210 may receive a control signal (e.g., a volume control signal received via an input button) related to the audio signal obtained from the external electronic device 102. The audio input interface 210 may include a plurality of audio input channels and may receive different audio signals corresponding to the plurality of different audio input channels through the plurality of different audio input channels. According to embodiments, additionally or alternatively, the audio input interface 210 may receive an audio signal input from another component (e.g., the processor 120 or the memory 130) of the electronic device 101.

The audio input mixer 220 may combine a plurality of input audio signals into at least one audio signal. For example, according to embodiments, the audio input mixer 220 may combine a plurality of analog audio signals input via the audio input interface 210 into at least one analog audio signal.

The analog-to-digital converter (ADC) 230 may convert an analog audio signal into a digital audio signal. For example, according to embodiments, the ADC 230 may convert the analog audio signal received via the audio input interface 210, additionally or alternatively, the analog audio signal combined via the audio input mixer 220 into a digital audio signal.

The audio signal processor 240 may perform various processes on the digital audio signal received through the ADC 230 or a digital audio signal received from another component of the electronic device 101. For example, according to embodiments, the audio signal processor 240 may perform following processing on one or more digital audio signals: changing a sampling rate, applying one or more filters, interpolation processing, amplification or attenuation of an entirety or a portion of a frequency band, noise processing (e.g., noise or echo reduction), channel change (e.g., conversion between mono and stereo), mixing, and/or extraction of a specified signal. According to embodiments, one or more functions of the audio signal processor 240 may be implemented in a form of an equalizer.

The DAC 250 may convert a digital audio signal into an analog audio signal. For example, according to embodiments, the DAC 250 may convert the digital audio signal processed by the audio signal processor 240, or a digital audio signal obtained from another component (e.g., the processor 120 or the memory 130) of the electronic device 101 into an analog audio signal.

The audio output mixer 260 may combine a plurality of audio signals to be output into at least one audio signal. For example, according to embodiments, the audio output mixer 260 may combine the analog audio signal from the DAC 250 and another analog audio signal (e.g., an analog audio signal received via the audio input interface 210) into at least one analog audio signal.

The audio output interface 270 may output the analog audio signal from the DAC 250, or additionally or alternatively, the analog audio signal combined by the audio output mixer 260 (e.g., the combination of the analog audio signal from the DAC 250 and another analog audio signal output from the electronic device 101 through the sound output module 155). The sound output module 155 may include, for example, a speaker such as a dynamic driver or a balanced armature driver, and/or a receiver. According to embodiments, the sound output module 155 may include a plurality of speakers. In this case, the audio output interface 270 may output audio signals having different channels (e.g., stereo or 5.1 channel) through some of the plurality of speakers. According to embodiments, the audio output interface 270 may be connected directly to the external electronic device 102 (e.g., an external speaker or headset) via the connection terminal 178 or may be wirelessly connected thereto via the wireless communication module 192, and may output the audio signal thereto.

According to embodiments, the audio module 170 may not separately include the audio input mixer 220 or the audio output mixer 260, but may use at least one function of the audio signal processor 240 to combine the plurality of digital audio signals to generate at least one digital audio signal.

According to embodiments, the audio module 170 may include audio amplification circuitry (e.g., speaker amplification circuitry) which may amplify the analog audio signal input via the audio input interface 210 and/or the audio signal to be output via the audio output interface 270. According to embodiments, the audio amplifier or amplification circuitry may be composed of a separate module from the audio module 170.

FIG. 3 is a block diagram showing the audio amplification circuitry according to embodiments.

Referring to FIG. 3, audio amplification circuitry 300 may include an audio output interface 310 and class-D amplification circuitry 320, and may be connected to an audio output device (e.g., a speaker) 330. According to embodiments, the audio amplification circuitry 300 may be included in the audio module 170.

According to embodiments, the audio output interface 310 may receive (or acquire) audio data from the audio signal processor (240 in FIG. 2).

The class-D amplification circuitry 320 according to embodiments may amplify a magnitude of audio data received via the audio output interface 310, based on an output voltage corresponding to output power of the audio data. For example, the class-D amplification circuitry 320 may convert analog type audio data (V_{IN}, for example: a sine wave signal) into a pulse type signal (v_{OUT} or V_{O}), and may amplify a feature (e.g., a pulse width, a pulse density, etc.) of the pulse type signal, based on the output power of the audio data (or an amplification strength of the audio data). The class-D amplification circuitry 320 may convert the amplified signal into an analog type signal that may be output to an outside via an audio output circuit (speaker) 330, and may provide the converted analog type signal to the audio output circuit (speaker). The class-D amplification circuitry 320 may consume a smaller amount of power as heat in an active device, as compared to a linear analog amplifier.

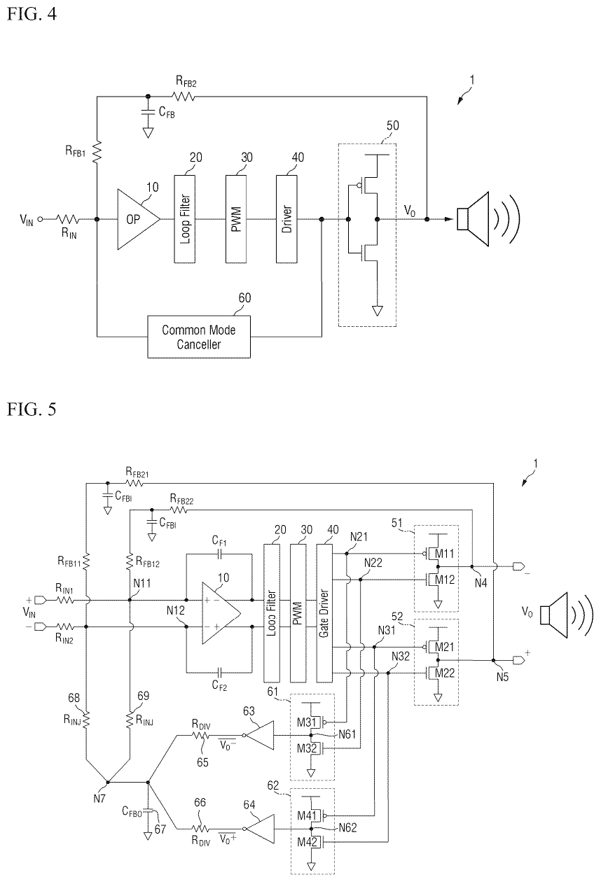

FIG. 4 is a conceptual diagram showing class-D amplification circuitry 1 according to embodiments. According to embodiments, the class-D amplification circuitry 1 may be used to implement the class-D amplification circuitry 320.

Referring to FIG. 4, the class-D amplification circuitry 1 may include an operational amplifier (OP amp) 10, a loop filter 20, a pulse width modulator (PWM) 30, a gate driver stage 40, an output stage 50, and/or a common mode canceller 60.

The operational amplifier 10 amplifies or attenuates the analog input signal V_{IN} and outputs the amplified or attenuated analog input signal. For example, the operational amplifier 10 amplifies or attenuates a signal, obtained by applying a feedback signal derived from an output signal V_{OUT} to the input signal V_{IN}, and outputs the amplified or attenuated analog signal.

The loop filter 20 performs low-pass filtering (e.g., filtering consistent with that characteristic of a low-pass filter) on an output signal from the operational amplifier 10 (e.g., a first signal) and outputs a resulting signal. For example, the loop filter 20 passes baseband frequency contents (audio signal) therethrough and filters higher frequency contents including out-of-band noise and signals around a carrier frequency (e.g., a PWM switching frequency), and harmonics thereof.

The pulse width modulator 30 performs pulse width modulation on the signal filtered via the loop filter 20 and outputs a modulated signal equivalent (or similar) thereto. The pulse width modulator 30 may be implemented as, for example, an analog or digital pulse width modulator circuit or may be implemented as, for example, an analog or digital pulse density modulator circuit. A modulation or carrier frequency of the pulse width modulator 30 may be controlled based on an operating clock (CLK) which generates a synchronization pulse and, for example, is provided to the class-D amplification circuitry 1.

The gate driver stage 40 generates a gate signal to be provided to the output stage 50 based on the modulated signal. For example, the gate driver stage 40 may include a signal buffer and/or another logic circuit so as to generate a gate signal to be provided to a gate terminal of each of transistors included in the output stage 50.

The output stage 50 may include a plurality of power transistors so as to generate the output signal V_{OUT} based on the gate signal received from the gate driver stage 40. For example, the power transistors may be switched based on the gate signal so as to generate the output signal V_{OUT}.

The common mode canceller 60 calculates a common mode noise contained in the gate signal and cancels the common mode noise from the input signal to the operational amplifier 10.

FIG. 5 is a circuit diagram specifically showing the class-D amplification circuitry of FIG. 4 according to embodiments.

Referring to FIG. 5, the class-D amplification circuitry 1 may include summing nodes N11 and N12 receiving the differential input signals V_{IN}, the operational amplifier (OP amp) 10 connected to the summing nodes, the loop filter 20 to filter the output signal from the OP amp 10, the pulse width modulator 30 that performs pulse width modulation on the filtered OP amp signal, the gate driver stage 40, the output stage 50 that outputs a differential output signal V_{O} to output nodes N4 and N5, and the common mode canceller 60. Hereinafter, redundant descriptions of the components 20, 30 and 40 as described in FIG. 4 are omitted.

The summing nodes N11 and N12 receive the differential input signal V_{IN}, a differential feedback signal VFB, and a differential common mode noise VCMN (hereinafter, referred to as a cancellation signal for convenience of description).

The operational amplifier 10 may be implemented as a differential operational amplification circuit according to embodiments. Positive (+) and negative (−) inputs of the differential input signal V_{IN} are respectively input to input resistors R_{IN1} and R_{IN2} (corresponding to input resistor R_{IN} illustrated in FIG. 4). In order to improve a frequency response and stability of the operational amplifier 10, and reduce noise distortion thereof, the operational amplifier 10 includes internal feedback capacitors CF₁ and CF₂ disposed between an input terminal and an output terminal of the operational amplifier 10 such that the internal feedback capacitors CF₁ and CF₂ and the input terminal and the output terminal of the operational amplifier 10 are connected to each other to form a closed loop structure.

A differential signal output from the operational amplifier 10 is generated as a gate signal which is provided to gate nodes N21, N22, N31, and N32 via the loop filter 20, the pulse width modulator 30, and the gate driver stage 40.

The output stage 50 includes the plurality of power transistors. For example, the output stage 50 may include a negative output stage 51 and a positive output stage 52. The negative output stage 51 includes a p-channel metal-oxide semiconductor field effect transistor (PMOS) power transistor M11 and an n-channel MOS (NMOS) power transistor M12 connected to, and disposed between, a power supply terminal and a power ground terminal. The positive output stage 52 includes a PMOS power transistor M21 and an NMOS power transistor M22 connected to, and disposed between, the power supply terminal and the power ground terminal.

A gate of the PMOS power transistor M11 is connected to the gate node N21, a gate of the NMOS power transistor M12 is connected to the gate node N22, a gate of the PMOS power transistor M21 is connected to the gate node N31, and a gate of the NMOS power transistor M22 is connected to a gate node N32. The gate driver stage 40 controls the gate signals output to each of the gate nodes N21, N22, N31, and N32 to generate the differential output signal V_{O} which is output to the output nodes N4 and N5 of the output stage 50.

The class-D amplification circuitry 1 includes a feedback loop path. The feedback loop path is formed as a system closed loop including the output nodes N4 and N5 and the summing nodes N11 and N12 of the class-D amplification circuitry 1, and system feedback impedance elements R_{FB11}, R_{FB12}, R_{FB21}, R_{FB22}, and C_{FBI} connected to, and disposed between, the output nodes N4 and N5 and the summing nodes N11 and N12. According to embodiments, the resistors R_{FB11} R_{FB12} may collectively correspond to the resistor R_{FB1} illustrated in FIG. 4, the resistors R_{FB21} and R_{FB22} may collectively correspond to the resistor R_{FB2} illustrated in FIG. 4, and the two capacitors C_{FBI} may collectively correspond to the capacitor C_{FB} illustrated in FIG. 4.

According to embodiments, the common mode canceller 60 may include pseudo output stages 61 and 62, inverters 63 and 64, a low pass filter (corresponding to a resistor 65, a resistor 66 and a filter capacitor 67), and pseudo resistors 68 and 69. According to embodiments, each of the pseudo resistors 68 and 69 may be implemented using a corresponding resistor.

Each of the pseudo output stages 61 and 62 is configured to generate a pseudo output signal similar to an actual output signal V_{O}, and may have the same configuration as (or a similar configuration to) that of each of the output stages 51 and 52. For example, when the output stage 50 includes the negative output stage 51 and the positive output stage 52 as described above which respectively include a combination of the PMOS power transistors M11 and the NMOS power transistors M12 and a combination of the PMOS power transistor M21 and the NMOS power transistor M22, the pseudo output stages 61 and 62 may include a negative pseudo stage 61 and a positive pseudo stage 62.

The negative pseudo stage 61 includes a PMOS pseudo transistor M31 and an NMOS pseudo transistor M32 connected in series to each other and connected to, and disposed between, a power supply terminal and a power ground terminal, wherein the PMOS pseudo transistor M31 and the NMOS pseudo transistor M32 have gates connected to the gate nodes N21 and N22, respectively. The positive pseudo stage 62 includes a PMOS pseudo transistor M41 and an NMOS pseudo transistor M42 connected in series to each other and connected to, and disposed between, a power supply terminal and a power ground terminal, wherein the PMOS pseudo transistor M41 and an NMOS pseudo transistor M42 have gates connected to the gate nodes N31 and N32, respectively.

The negative pseudo stage 61 is composed of the same MOS transistors as (or similar MOS transistors to) those of the negative output stage 51 and receives the same input signal (the gate signal of N21 and N22) as (or similar input signals to) that which the negative output stage 51 receives. According to embodiments, the pseudo transistor M31 and the pseudo transistor M32 may have the same or similar sizes, and the power transistor M11 and the power transistor M12 may have the same or similar sizes. However, each of the pseudo transistors M31 and M32 may have a smaller size than that of each of the power transistors M11 and M12, respectively (e.g., M11>>M31 and M12>>M32). A ratio between the sizes of the PMOS pseudo transistor M31 and the PMOS power transistor M11 is equal (or similar) to a ratio between the sizes of the NMOS pseudo transistor M32 and the NMOS power transistor M12. Above size of transistor refers a size of a physical dimension or an area of transistor in view of a semiconductor layout.

Similarly, the positive pseudo stage 62 is composed of the same MOS transistors as (or similar MOS transistors to) those of the positive output stage 52 and receives the same input signal (the gate signal of N31 and N32) as (or a similar input signal to) that which the positive output stage 52 receives. According to embodiments, the pseudo transistor M41 and the pseudo transistor M42 may have the same or similar sizes, and the power transistor M21 and the power transistor M22 may have the same or similar sizes. However, each of the pseudo transistors M41 and M42 may have a smaller size than that of each of the power transistors M21 and M22, respectively (for example, M21>>M41 and M22>>M42). A ratio between the sizes of the PMOS pseudo transistor M41 and the PMOS power transistor M21 is equal (or similar) to a ratio of the sizes of the NMOS pseudo transistor M42 and the NMOS power transistor M22.

That is, each of the pseudo stages 61 and 62 has the same configuration as (or a similar configuration to) that of each of the output stages 51 and 52. Further, each of the pseudo stages 61 and 62 receives the same input signal as (or a similar input signal to) that which each of the output stages 51 and 52 receives. However, the size of each of the pseudo stages 61 and 62 is smaller than the size of each of the output stages 51 and 52. Thus, a pseudo output signal may contain signal components that are the same as (or similar to) or proportional to those of the actual output signal (e.g., the differential output signal V_{O}).

The inverters 63 and 64 may be respectively connected to outputs of the pseudo stages 61 and 62. For example, the inverter 63 may be connected to an output node N61 of the negative pseudo stage 61, may invert a negative pseudo output signal received from the output node N61, and may output an inverted negative pseudo output signal V̅ₒ̅⁻̅. The inverter 64 may be connected to an output node N62 of the positive pseudo stage 62, may invert a positive pseudo output signal received from the output node N62, and may output an inverted positive pseudo output signal V̅ₒ̅⁺̅.

The low pass filter (corresponding to the resistor 65, the resistor 66 and the filter capacitor 67) is connected to outputs of the inverters 63 and 64. The low pass filter includes filter resistors R_{DIV} (corresponding to the resistor 65 and the resistor 66) respectively connected to the inverters 63 and 64, and a filter capacitor C_{FBO} 67 connected to a common node N7 of the resistors R_{DIV}. According to embodiments, the filter resistors R_{DIV} may have the same resistance value as (an equal resistance value to or similar resistance values to) that of the feedback resistors R_{FB21} and R_{FB22}, and the filter capacitor C_{FBO} may have an equivalent (or similar) capacitance to that of a combination of two feedback capacitors C_{FB} connected parallel to each other, that is, two times of the feedback capacitance being 2C_{FB}. According to embodiments, each of the filter resistors R_{DIV} (corresponding to the resistor 65 and the resistor 66) may have the same resistance value as (or similar resistance values to) that of a corresponding feedback receiver (e.g., the feedback resistors R_{FB22} and R_{FB21}, respectively) or to both the feedback resistors R_{FB22} and R_{FB21}. According to embodiments, the filter capacitor C_{FBO} may have a capacitance equal (or similar) to that of one (or each) of the two feedback capacitors C_{FB}.

The inverted negative pseudo output signal V̅ₒ̅⁻̅ may pass through the low-pass filter (e.g., the resistor 65 and the filter capacitor 67) while the inverted positive pseudo output signal V̅ₒ̅⁺̅ may pass through the low-pass filter (e.g., the resistor 66 and the filter capacitor 67). Then, the resulting output signals may both be summed with each other at the common node N7. A signal of the common node N7 may be provided to the positive summing node N11 via the pseudo resistor R_{INJ} (69) and may be provided to the negative summing node N12 via the pseudo resistor R_{INJ} (68). In this regard, each pseudo resistor R_{INJ} has the same resistance value as (an equal resistance value to or similar resistance values to) that of each of the feedback resistors R_{FB11} and R_{FB12} of the feedback loop. According to embodiments, each pseudo resistor R_{INJ} 68 and 69 may have the same resistance value as (or similar resistance values to) that of a corresponding feedback receiver (e.g., the feedback resistors R_{FB11} and R_{FB12}, respectively) or to both the feedback resistors R_{FB11} and R_{FB12}. According to embodiments, a combination of the low pass filter and the pseudo resistor pair has an impedance equal (or similar) to an impedance of the feedback loop path.

The differential output signal V_{O} from the output nodes N4 and N5 of the class-D amplification circuitry 1 is produced via BD modulation. Thus, the common mode noise is mixed with the signal fed back to the summing nodes N11 and N12 via the system closed loop connection. If the class-D amplification circuitry 1 is ideal, there is no challenge. However, when the class-D amplification circuitry 1 is implemented as an actual product, the common mode noise may negatively affect the input. This may affect overall performance of a device including the class-D amplification circuitry 1. Thus, in order to cancel the common mode noise, the common mode canceller 60 may imitate the differential output signal V_{O} in a phase-inverted manner such that the inverted pseudo output signal is applied to the differential input signal to the class-D amplification circuitry 1, thereby lowering THD (Total Harmonic Distortion) of the class-D amplification circuitry 1. According to embodiments, the class-D amplification circuitry 1 (and/or the class-D amplification circuitry 2 discussed below) may amplify a magnitude of received audio data and cancel the common mode noise such that the resulting amplified signal omits (or includes a reduced amount of) the common mode noise. According to embodiments, the class-D amplification circuitry 1 (and/or the class-D amplification circuitry 2 discussed below) may output the resulting amplified signal to an audio output device 330 (e.g., a speaker). According to embodiments, the audio output device may output the resulting amplified signal as an audio (e.g., audible) signal.

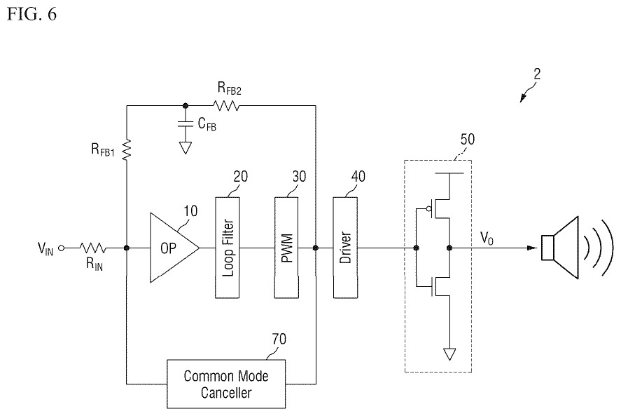

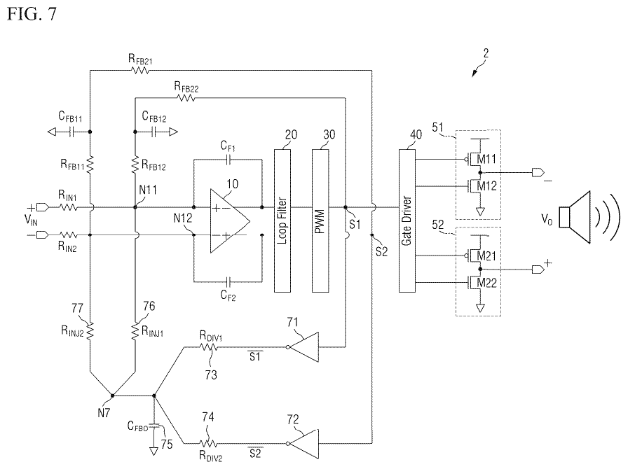

FIG. 6 is a conceptual diagram showing class-D amplification circuitry 2 according to embodiments, and FIG. 7 is a detailed circuit diagram showing the class-D amplification circuitry 2 of FIG. 6.

Referring to FIGS. 6 and 7, the class-D amplification circuitry 2 may include the operational amplifier 10, the loop filter 20, the pulse width modulator 30, the gate driver stage 40, the output stage 50, and a common mode canceller 70. For convenience of description, descriptions duplicate with those as set forth above with reference to FIG. 4 and FIG. 5 are omitted.

In the class-D amplification circuitry 2 according to embodiments, a feedback loop path may include the summing nodes N11 and N12 and output nodes S1 and S2 of the pulse width modulator 30. That is, the feedback resistors R_{FB11}, R_{FB12}, R_{FB21}, and R_{FB22} and the feedback capacitors C_{FB11} and C_{FB12} may be connected to, and disposed between, the summing nodes N11 and N12 and the output nodes S1 and S2 of the pulse width modulator 30, that is, input nodes of the gate driver stage 40. According to embodiments, the feedback capacitors C_{FB11} and C_{FB12} may be the same as (or similar to) the two feedback capacitors C_{FB}.

The feedback loop path generates a feedback signal based on a modulated signal at each of the output nodes S1 and S2 of the pulse width modulator 30. For example, each of the feedback resistors R_{FB21} and R_{FB22} may have one end connected to each of the output nodes S1 and S2. Each feedback capacitor C_{FB} may be connected to, and disposed between, the other end of each feedback resistor and a ground voltage terminal. Each of the filter resistors R_{FB11} and R_{FB12} may be connected to, and disposed between, the other end of each feedback resistor (e.g., the feedback resistors R_{FB21} and R_{FB22}) and each of the summing nodes N11 and N12, and may provide the feedback signal to each of the summing nodes.

The common mode canceller 70 may be connected to, and disposed between, the output nodes S1 and S2 of the pulse width modulator 30 and the summing nodes N11 and N12 based on a configuration of the feedback loop path. However, unlike the above example of FIG. 4 and FIG. 5, the common mode canceller 70 includes inverters 71 and 72, a low pass filter (corresponding to the filter resistor 73, the filter resistor 74 and the filter capacitor 75), and pseudo resistors 76 and 77 and is free of (e.g., omits) the pseudo stages 61 and 62.

The input signal provided to the feedback loop path is a modulated signal provided to the output nodes S1 and S2 of the pulse width modulator 30, and is a signal which does not pass through the power transistors in the output stages 51 and 52. Thus, the signal of the output nodes S1 and S2 of the pulse width modulator 30 which is used as an input signal to the feedback loop path is used as an input signal provided to the common mode canceller 70.

As described above, the common mode noise is mixed with the signal fed back to the summing nodes N11 and N12 via the feedback loop path. Thus, the inverted pseudo signal generated by the common mode canceller 70 may be generated in a corresponding manner to the signal of the feedback loop path, thereby cancelling the common mode noise. That is, the differential input signal V_{IN}, the feedback signal, and the inverted pseudo signal may be provided to the summing nodes and may be summed in the operational amplifier 10.

Conventional devices and methods for implementing class D amplification circuitry are unable to sufficiently cancel common mode noise. As a result, the conventional devices and methods rely on higher-performance (and higher-cost) amplifiers for implementing class D amplification circuitry.

However, according to embodiments, improved devices and methods are provided for implementing class D amplification circuitry. For example, the improved devices and methods include a common mode canceller that outputs an inverted pseudo output signal that, when applied to a feedback signal, cancels the common mode noise in the feedback signal. Accordingly, the improved devices and methods may overcome the deficiencies of the conventional devices and methods to at least improve the cancellation of the common mode noise, thereby enabling the use of lower-performance (and lower-cost) amplifiers for implementing the class D amplification circuitry.

According to embodiments, operations described herein as being performed by the network environment 100, the electronic device 101, the electronic device 102, the electronic device 104, the server 108, the processor 120, the input module 150, the sound output module 155, the audio module 170, the sensor module 176, the haptic module 179, the camera module 180, the power management module 188, the communication module 190, the subscriber identification module 196, the antenna module 197, the main processor 121, the auxiliary processor 123, the wireless communication module 192, the wired communication module 194, the audio input interface 210, the audio input mixer 220, the ADC 230, the audio signal processor 240, the DAC 250, the audio output mixer 260, the audio output interface 270, the audio amplification circuitry 300, the audio output interface 310, the class-D amplification circuitry 320, the audio output device 330, the class-D amplification circuitry 1, the operational amplifier 10, the loop filter 20, the pulse width modulator 30, the gate driver stage 40, the output stage 50, the common mode canceller 60, the class-D amplification circuitry 2 and/or the common mode canceller 70 may be performed by processing circuitry. The term ‘processing circuitry,’ as used in the present disclosure, may refer to, for example, hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The various operations of methods described above may be performed by any suitable device capable of performing the operations, such as the processing circuitry discussed above. For example, as discussed above, the operations of methods described above may be performed by various hardware and/or software implemented in some form of hardware (e.g., processor, ASIC, etc.).

The software may comprise an ordered listing of executable instructions for implementing logical functions, and may be embodied in any “processor-readable medium” for use by or in connection with an instruction execution system, apparatus, or device, such as a single or multiple-core processor or processor-containing system.

The blocks or operations of a method or algorithm and functions described in connection with embodiments disclosed herein may be embodied directly in hardware, in a software module executed by a processor, or in a combination of the two. If implemented in software, the functions may be stored on or transmitted over as one or more instructions or code on a tangible, non-transitory computer-readable medium. A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD ROM, or any other form of storage medium known in the art.

Although embodiments of the present disclosure have been described above with reference to the accompanying drawings, the present disclosure may not be limited thereto and may be implemented in various different forms. Those of ordinary skill in the technical field to which the present disclosure belongs will be able to understand that the present disclosure may be implemented in other specific forms without changing the technical idea or essential features of the present disclosure. Therefore, it should be understood that embodiments as described above are not restrictive but illustrative in all respects.

What is claimed is:

1. Class-D amplification circuitry comprising:
an operational amplifier configured to,
receive a differential input signal via summing nodes, and
output a first signal;
a loop filter configured to,
low-pass filter the first signal to generate a filtered signal;
a pulse width modulator configured to perform pulse width modulation on the filtered signal to generate a modulated signal;
a gate driver stage configured to generate a gate signal based on the modulated signal;
an output stage configured to generate a differential output signal based on the gate signal; and
a common mode canceller connected between an input node of the output stage and the summing nodes, the common mode canceller being configured to,
generate an inverted pseudo output signal based on the differential output signal, and
provide the inverted pseudo output signal the summing nodes, the inverted pseudo output signal cancelling a common mode noise when applied to a feedback signal provided to the summing nodes.

2. The class-D amplification circuitry of claim 1, wherein the common mode canceller comprises:
a pseudo stage pair, each pseudo stage among the pseudo stage pair includes at least one pseudo transistor, the at least one pseudo transistor corresponding to at least one power transistor of the output stage, and the pseudo stage pair being configured to generate a differential pseudo output signal based on the gate signal;
an inverter pair configured to invert the differential pseudo output signal to generate an inverted differential pseudo output signal;
a low pass filter configured to perform low-pass filtering on the inverted differential pseudo output signal to generate a filtered inverted pseudo output signal; and
a pseudo resistor pair configured to differentially distribute the filtered inverted pseudo output signal to the summing nodes.

3. The class-D amplification circuitry of claim 2, wherein the output stage comprises:
a positive output stage configured to output a positive output signal to a first output node, the positive output signal being based on a first gate signal received via a first gate node and a second gate signal received via a second gate node; and
a negative output stage configured to output a negative output signal to a second output node, the negative output signal being based on a third gate signal received via a third gate node and a fourth gate signal received via a fourth gate node,
wherein the pseudo stage pair includes,
a positive pseudo stage connected to the first gate node and the second gate node, the positive pseudo stage being configured to generate a positive pseudo output signal, and
a negative pseudo stage connected to the third gate node and the fourth gate node, the negative pseudo stage being configured to generate a negative pseudo output signal.

4. The class-D amplification circuitry of claim 2, wherein a size of the at least one pseudo transistor is smaller than a size of the at least one power transistor.

5. The class-D amplification circuitry of claim 3, wherein the inverter pair includes:
a first inverter for inverting the positive pseudo output signal; and
a second inverter for inverting the negative pseudo output signal.

6. The class-D amplification circuitry of claim 2, further comprising a feedback loop path connected between output nodes of the output stage and the summing nodes, the feedback loop path being configured to,
generate the feedback signal, and
provide the feedback signal to the summing nodes.

7. The class-D amplification circuitry of claim 6, wherein a combination of the low pass filter and the pseudo resistor pair has an impedance equal to an impedance of the feedback loop path.

8. Class-D amplification circuitry comprising:
an operational amplifier configured to,
receive a differential input signal and a feedback signal via summing nodes, and
output a first signal;
a loop filter configured to low-pass filter the first signal to generate a filtered signal;
a pulse width modulator configured to perform pulse width modulation on the filtered signal to generate a modulated signal;
a gate driver stage configured to generate a gate signal based on the modulated signal;
an output stage configured to generate a differential output signal based on the gate signal; and
a common mode canceller configured to,
generate an inverted pseudo signal based on the modulated signal, and
provide the inverted pseudo signal to the summing nodes.

9. The class-D amplification circuitry of claim 8, wherein the common mode canceller comprises:
an inverter pair configured to invert the modulated signal to generate an inverted modulated signal;
a low pass filter configured to low-pass filter the inverted modulated signal to generate a filtered inverted modulated signal; and
a pseudo resistor pair configured to differentially distribute the filtered inverted modulated signal to the summing nodes.

10. The class-D amplification circuitry of claim 9, wherein
the feedback signal is provided to the summing nodes via a pair of feedback loop paths; and
each feedback loop path among the pair of feedback loop paths comprises:
a first feedback resistor having one end connected to an input of the gate driver stage,
a first feedback capacitor connected to another end of the first feedback resistor and a ground voltage terminal, and
a second feedback resistor connected between the other end of the first feedback resistor and one of the summing nodes.

11. The class-D amplification circuitry of claim 10, wherein the low pass filter comprises:
a pair of filter resistors, each filter resistor among the pair of filter resistors having one end connected to an output of a corresponding inverter of an inverter pair; and
a filter capacitor connected to,
another end of each filter resistor among the pair of filter resistors, and
a ground voltage terminal, each pseudo resistor among the pseudo resistor pair is configured to provide the inverted pseudo signal to a corresponding summing node among the summing nodes, and each pseudo resistor among the pseudo resistor pair being connected to,
the other end of a corresponding filter resistor among the pair of filter resistors, and
a corresponding summing node among the summing nodes.

12. The class-D amplification circuitry of claim 11, wherein
each filter resistor among the pair of filter resistors has a resistance value equal to a resistance value of the first feedback resistor; and
the filter capacitor has a capacitance equal to a capacitance of the first feedback capacitor; and
each pseudo resistor among the pseudo resistor pair has a resistance value equal to a resistance value of the second feedback resistor.

13. An audio amplification circuitry comprising:
an audio output interface for receiving audio data and converting the audio data into a differential input signal;
class-D amplification circuitry configured to,
convert the differential input signal into a pulse-type differential output signal, and
amplify the pulse-type differential output signal based on an output power to generate an amplified differential output signal; and
a speaker for outputting the amplified differential output signal,
wherein the class-D amplification circuit includes:
an operational amplifier configured to,
receive the differential input signal and a feedback signal via summing nodes, and
output a first signal;
a loop filter configured to low-pass filter the first signal to generate a filtered signal;
a pulse width modulator configured to perform pulse width modulation on the filtered signal to generate a modulated signal;
a gate driver stage configured to generate a gate signal based on the modulated signal;
an output stage configured to generate a differential output signal based on the gate signal;
a feedback loop path via which the feedback signal is provided to the summing nodes, the feedback signal being based on the differential output signal; and
a common mode canceller configured to,
generate a differential pseudo output signal corresponding to the feedback signal,
invert the differential pseudo output signal to generate an inverted differential pseudo output signal, and
provide the inverted differential pseudo output signal to the summing nodes.

14. The audio amplification circuitry of claim 13, wherein
the inverted differential pseudo output signal cancels a common mode noise when applied to the feedback signal to generate a noise-canceled feedback signal; and
the operational amplifier is configured to receive the noise-cancelled feedback signal and the differential input signal via the summing nodes.

15. The audio amplification circuitry of claim 13, wherein the feedback loop path is connected to:
output nodes of the output stage; and
the summing nodes.

16. The audio amplification circuitry of claim 15, wherein the common mode canceller comprises:
a pseudo stage pair, each pseudo stage among the pseudo stage pair includes at least one pseudo transistor corresponding to the output stage, the pseudo stage pair being configured to generate a differential pseudo output signal based on the gate signal;
an inverter pair configured to invert the differential pseudo output signal to generate an inverted differential pseudo output signal;
a low pass filter configured to perform low-pass filtering on the inverted differential pseudo output signal to generate a filtered inverted pseudo output signal; and
a pseudo resistor pair configured to differentially distribute the filtered inverted pseudo output signal to the summing nodes.

17. The audio amplification circuitry of claim 16, wherein the output stage comprises:
a positive output stage configured to output a positive output signal to a first output node, the positive output signal being based on a first gate signal received via a first gate node and a second gate signal received via a second gate node; and
a negative output stage configured to output a negative output signal to a second output node, the negative output signal being based on a third gate signal received via a third gate node and a fourth gate signal received via a fourth gate node,
wherein the pseudo stage pair includes,
a positive pseudo stage connected to the first gate node and the second gate node, the positive pseudo stage being configured to generate a positive pseudo output signal, and
a negative pseudo stage connected to the third gate node and the fourth gate node, the negative pseudo stage being configured to generate a negative pseudo output signal.

18. The audio amplification circuitry of claim 17, wherein a combination of the low pass filter and the pseudo resistor pair has an impedance equal to an impedance of the feedback loop path.

19. The audio amplification circuitry of claim 17, wherein a size of the at least one pseudo transistor is smaller than a size of at least one power transistor included in each output stage among the positive output stage and the negative output stage.

20. The audio amplification circuitry of claim 15, wherein the common mode canceller comprises:
an inverter pair for inverting the differential pseudo output signal to generate an inverted differential pseudo output signal;
a low pass filter for performing low-pass filtering on the inverted differential pseudo output signal to generate a filtered inverted pseudo output signal; and
a pseudo resistor pair configured to differentially distribute the filtered inverted pseudo output signal to the summing nodes.
